(19) United States
(12) Patent Application Publication
(10) Pub. No.: US 2026/0096378 A1
(43) Pub. Date: Apr. 2, 2026

(54) APPARATUSES AND METHODS FOR CLEANING OBJECTS

(71) Applicant: Taiwan Semiconductor Manufacturing Company, Ltd., Hsinchu (TW)

(72) Inventors: LIN TZU KEN, Taichung City (TW); NAI-CHIA CHANG, Hsinchu County (TW); CHING-HORNG CHEN, Hsinchu County (TW); KUANG-WEI CHENG, Hsinchu City (TW); CHEN-SHIEN CHEN, Zhubei City (TW)

(73) Assignee: Taiwan Semiconductor Manufacturing Company, Ltd., Hsinchu (TW)

(21) Appl. No.: 18/898,864

(22) Filed: Sep. 27, 2024

(51) Int. Cl. H01L 21/67; H01L 21/677

(52) U.S. Cl. CPC H10P 72/0414; H10P 72/33

(57) ABSTRACT

Apparatuses and methods are provided for cleaning objects, such as semiconductor wafers. The apparatuses include an ion flow device that includes an ionizer configured to generate an electric field sufficient to electrically charge gas molecules of a filtered gas to produce an ionized gas and a nozzle configured to expel the ionized gas toward a surface of an object to neutralize electrostatic charges of particles on the surface, a blower device configured to propel the filtered gas to the ionizer and the ionized gas out of the nozzle, passages disposed on first and second sides of the ion flow device that are in fluidic communication with the surface of the object, and an exhaust device configured to flow the ionized gas from the surface of the object through the first and second passages to remove the particles from the surface.

### BACKGROUND

The semiconductor integrated circuit (IC) industry has continued its rapid growth in recent years. Technological advancements in IC materials and design have led to continuous improvements in the generations of ICs. With each new generation, the circuits become smaller and more complex than their predecessors, resulting in higher functional density (i.e., the number of interconnected devices per chip area) and smaller geometric sizes (i.e., the smallest component or line that can be created using a fabrication process). This scaling down process has been beneficial in increasing production efficiency and reducing associated costs. However, as feature sizes continue to shrink, the manufacturing process becomes more challenging, and it becomes increasingly difficult to ensure the reliability of semiconductor devices. As a result, the industry faces the ongoing challenge of developing processes that can create smaller, more reliable ICs.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 schematically represents a cross-sectional view of an example wafer transfer system at one stage in a semiconductor manufacturing process in accordance with some embodiments;

FIG. 2 schematically represents a cross-sectional view of an example of the wafer cleaning apparatus of FIG. 1 in accordance with some embodiments;

FIGS. 3-5 illustrate various views of the exemplary upper particle-removing device of FIGS. 1 and 2 in accordance with some embodiments;

FIG. 6 is a flowchart illustrating an exemplary method for cleaning an object, such as a semiconductor wafer, in accordance with some embodiments;

FIGS. 7-9 illustrate various exemplary aspects of the method of FIG. 6, in accordance with some embodiments; and

FIGS. 10-12 include plots representing certain results of various experimental investigations leading to aspects of some of the embodiments disclosed herein.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

Some embodiments of the disclosure will now be described with reference to the drawings, wherein like reference numerals are generally used to refer to like elements throughout. In the following description, for purposes of explanation, numerous specific details are set forth in order to provide a thorough understanding of the claimed subject matter. It is evident, however, that the claimed subject matter may be practiced without these specific details. In other instances, structures and devices are illustrated in block diagram form in order to facilitate describing the claimed subject matter.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

During the manufacture of semiconductor devices, semiconductor wafers are subjected to different processes (e.g., wet etching, dry etching, ashing, stripping, metal plating, and/or chemical mechanical polishing) in different processing chambers. During the intervals between different processes, wafers are typically transferred in batches and temporarily stored in wafer storage devices (also referred to as carriers). Each batch of wafers may be vertically stacked in a wafer storage device and supported by a support frame having a plurality of individual wafer shelves or wafer slots within the wafer storage device. These wafer storage devices, often referred to as front-opening unified pods (FOUPs), may provide a humidity and contaminant controlled environment to maintain the integrity of the wafer and/or the fabrication layers in and/or on the wafer. These wafer storage devices typically maintain an ultra-clean environment.

The wafer storage devices and the processing chambers may have different moisture or contaminant levels requirements. Therefore, the wafers may be transferred from the wafer storage device to a processing chamber through an interface module, such as facility interfaces or Equipment Front End Modules (EFEMs), which functions to preserve the separate environments of the wafer storage devices and the processing chambers. However, despite the many precautions performed to preserve the conditions of the wafers, moisture and contaminants in the form of particles and/or chemical gases may accumulate on the wafers during the manufacturing process. In particular, the presence of an electrostatic charge on surfaces of the wafers may result in particles adhering to surfaces of the wafers. These particles and/or other contaminants may have the potential to form defects in the fabrication layers on the wafer that can result in defective semiconductor devices and, thus, loss of production yield.

Presented herein are exemplary systems and methods configured to remove and/or reduce contaminants present on surfaces of the wafers. In some examples, the systems and methods include wafer cleaning apparatuses disposed within interface modules, such as EFEMs, that neutralize or reduce electrostatic charges and remove particles and other contaminates from surfaces of wafers prior to the wafers being transferred into a processing chamber. For convenience, the systems and methods will be described herein in reference to semiconductor wafers at intermediate stages of a semiconductor manufacturing process and an interface module, specifically an EFEM, for transferring the wafers between wafer storage devices and processing chambers. However, the systems and methods are not limited to this application and/or stage of the semiconductor production process, and may be applicable to other systems and products.

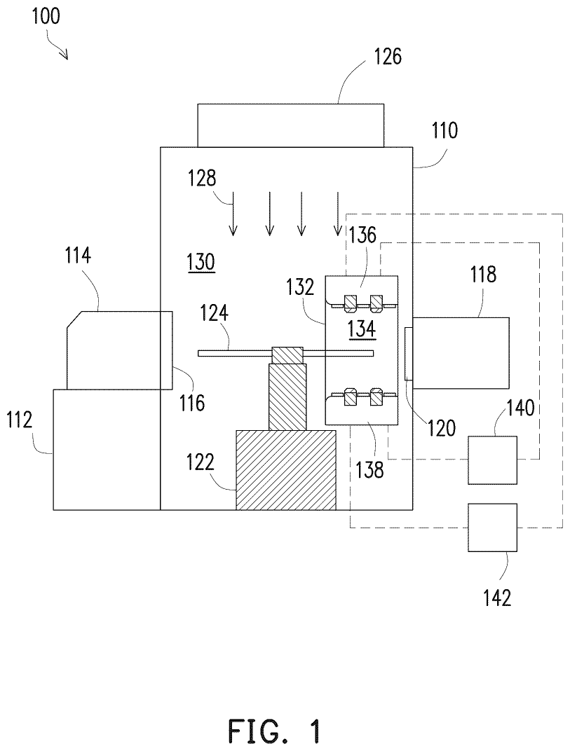

FIG. 1 is a cross-sectional view of an example wafer transfer system 100 at one stage in a semiconductor manufacturing process in accordance with an embodiment. In this example, the system 100 includes one or more devices and/or modules, such as an interface module 110 (e.g., EFEM), a load port 112, a wafer storage device 114, and a load lock module 118. The load lock module 118 may be coupled with a processing module (not shown) configured to perform a manufacturing process involving the processing of one or more wafers, such as an exemplary wafer 124. According to some examples, the system 100 may be configured to transfer the wafer 124 from the wafer storage device 114, through the interface module 110, through the load lock module 118, and into a processing module (and vice versa). The number of processing tools and/or modules may vary according to different manufacturing procedures associated with semiconductor wafer processing. In some examples, processing system 100 may be provided in a large-space cleanroom that provides a cleanroom environment having a lower concentration of particles and a lower relative humidity than an ambient environment.

In some examples, the wafer 124 may include a plurality of layers, such as semiconductor layers, conductor layers, and/or insulator layers. The semiconductor layer may include, for example, a base semiconductor having a crystalline, polycrystalline, amorphous, and/or other suitable structure, such as silicon or germanium; a compound semiconductor including silicon carbide, gallium arsenide, gallium phosphide, indium arsenide, and/or indium antimonide; an alloy semiconductor including SiGe, GaAsP, AlInAs, AlGaAs, GaInAsP, GaInP, and/or GaInAsP; any other suitable material; and/or combinations thereof. In some examples, the combination of semiconductors may take the form of a mixture or gradient, such as a substrate in which the ratio of Si and Ge varies at different locations. In some embodiments, the wafer 124 may include a layered semiconductor. Examples may include layering of semiconductor-on-insulator layers, such as for producing silicon-on-insulator (“SOI”) substrates, silicon-on-sapphire substrates, silicon-germanium-on-insulator substrates; or delamination of a semiconductor on glass to produce a thin film transistor (“TFT”). The wafer 124 may undergo a number of processing operations, such as photolithography, etching, and/or doping, prior to forming a completed die.

In some examples, the interface module 110 includes walls that define a transfer chamber 130 of the interface module 110. The interface module 110 may be configured to provide a transfer chamber environment within the transfer chamber 130 having a higher cleanliness level and/or a lower humidity level than a clean room. For example, the temperature within the transfer chamber environment can be maintained at a consistent temperature such as, for example, between 20° C. and 25° C. (e.g., 22° C.), and a consistent humidity level such as, for example, between 20% rh and 45% rh. In some examples, the interface module 110 may include a fan filter unit 126 configured to produce and/or maintain the transfer chamber environment within the transfer chamber 130 of the interface module 110. The fan filter unit 126 may include a fan unit (not shown) and a filter unit (not shown). For example, the fan unit may draw air from the clean room environment or a gas from another source into the transfer chamber 130 of the interface module 110, filter the air or gas with the filter unit, and then input the air or gas into the transfer chamber 130 to produce a flow 128 of the air or gas. The air or gas within the transfer chamber 130 may be exhausted from the interface module 110, for example, through an exhaust vent at or adjacent to a bottom portion of the interface module 110. In some examples, an exhaust pump (not shown) may be provided that is configured to promote removal of the air or gas from the transfer chamber 130. The exhaust pump may be, for example, a centrifugal pump, an air cooled pumps (ACPs), or another type of pump to eliminate gases in the transfer chamber 130. In some examples, the transfer chamber environment within the transfer chamber 130 of the interface module 110 may be configured to provide a level of environmental separation of the wafers 124 from sources of contamination and/or cross-contamination (e.g., contamination from human operators).

In some examples, the interface module 110 is configured as a facility interface, EFEM, or other type of interface for transferring the wafers 124 from the wafer storage device 114 to another module and/or device (e.g., the load lock module 118 or another wafer storage device). In some examples, the walls of the transfer chamber 130 may include a first opening sealed by operation of a first interface door 116 and a second opening sealed by operation of a second interface door 120. The first interface door 116 may be opened to provide access to an interior compartment of the wafer storage device 114 and the second interface door 120 may be opened to provide access to an interior compartment of the load lock module 118. The interface module 110 may include a handling machine 122, such as a robotic arm, rail-based extension member, or other mechanical device. The handling machine 122 may be configured to transfer the wafer 124 between the wafer storage device 114 and the load lock module 118 for subsequent processing within the processing module. In some examples, the handling machine 122 may include a vacuum-controlled transfer robot that includes a vacuum system configured to control a movement speed of a robotic arm thereby allowing for relatively slow and precise movements.

In some examples, the wafer storage device 114 may be disposed on top of the load port 112 and adjacent to the interface module 110. For example, the wafer storage device 114 may be positioned on a top surface of the load port 112. In some examples, the wafer storage device 114 is configured as a Standard Mechanical Interface (SMIF) or FOUP to hold a plurality of wafers 124. The wafers 124 may be configured for batch processing, such as vertically stacked in the wafer storage device 114. In one example, the wafer storage device 114 may include a plurality of support frames with a plurality of individual wafer shelves or wafer slots therein to hold a plurality of the wafers 124. In one example, the wafer storage device 114 may include a movable cassette to hold a plurality of the wafers 124. In some examples, the wafer storage device 114 is configured to provide an ultra-clean environment, such as a humidity and contaminant controlled environment, to maintain the integrity of the plurality of wafers 124.

In some examples, an Overhead Hoist Transport (OHT) (not shown) transfers the wafer storage device 114 from another module, such as a stocker (not shown), to the load port 112. In some examples, the load port 112 may be connected to a Remote Load Lock (RLL) module (not shown) to receive the wafer 124. For example, a robotic device may be used to transfer the wafer 124 from between the load port 112 and the RLL module. In some examples, the load port 112 may be in gaseous communication with the wafer storage device 114 while the wafer storage device 114 is disposed thereon to provide an wafer storage environment (e.g., ultra-clean environment) within the wafer storage device 114. For example, gas may be added to the wafer storage device 114 through a gas inlet from the load port 112 and gas may be exhausted from the wafer storage device 114 through a gas outlet. In one example, the wafer storage device 114 may include a diffuser or other vent plate(s) located in an interior chamber of the wafer storage device 114 to deliver input gases at different locations within the wafer storage device 114. In some examples, the load port 112 may include one or more pumps, such as centrifugal pumps, air Cooled Pumps (ACPs), or other types of pumps to remove gases, supply gases, and/or create a vacuum in the wafer storage device 114.

The load lock module 118 may be disposed between the interface module 110 and the processing module (not shown). The load lock module 118 may be configured to maintain an environment within the processing module by providing separation thereof from the interface module 110. In some examples, the load lock module 118 may receive the wafer 124 through the second opening by opening of the second interface door 120 of the interface module 110. When the wafer 124 is inserted into the load lock module 118, the load lock module 118 may be sealed by closing the second interface door 120. The load lock module 118 may be configured to create a load lock environment compatible with the process module in accordance with the processing operations associated with the wafer 124. The load lock environment may be controlled by changing the gas content within the load lock module 118, such as by adding gas, venting, creating a vacuum, and/or other procedures for adjusting the load lock environment. The load lock module 118 may include one or more pumps (not shown) for exhausting gas, such as corrosive gas, from the internal chamber of the load lock module 118. The one or more pumps of the load lock module 118 may be centrifugal pumps, air Cooled Pumps (ACPs), roots vacuum pumps (RUVAC), or other types of pumps to eliminate corrosive gases, supply inert gases, and/or create a vacuum in the load lock environment. When the appropriate environment is achieved within the load lock module 118, the wafer 124 may be transferred to the process module.

The interface module 110 includes a wafer cleaning apparatus 132 within the transfer chamber 130. In some examples, the wafer cleaning apparatus 132 may be positioned adjacent to the second opening and the second interface door 120. In some examples, the wafer cleaning apparatus 132 may include a first or upper particle-removing device 136, a second or lower particle-removing device 138, and a space or passage 134 therebetween. The wafer cleaning apparatus 132 may be configured to allow the handling machine 122 to move the wafer 124 through the passage 134 prior to inserting the wafer 124 into the load lock module 118. As the wafer 124 moves through the passage 134, the upper particle-removing device 136 and the lower particle-removing device 138 may be operated to remove particles from surfaces of the wafer 124.

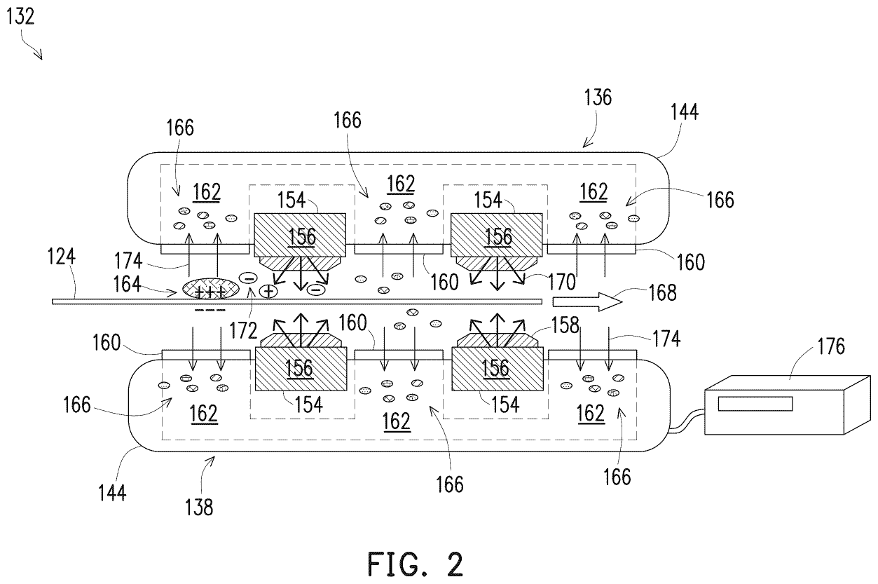

Referring now to FIG. 2, and with continued reference to FIG. 1, an example of the wafer cleaning apparatus 132 is presented. In this example, the upper particle-removing device 136 and the lower particle-removing device 138 include substantially the same structures. However, the wafer cleaning apparatus 132 is not limited to this example, and the upper particle-removing device 136 and the lower particle-removing device 138 may have different structures. In general, the upper particle-removing device 136 and the lower particle-removing device 138 each include a body 144 having one or more ion flow devices 154 coupled thereto and exhaust openings 160 adjacent to the ion flow devices 154 that are in fluidic communication with exhaust passages 162 within the body 144.

In some examples, the system 100 may include a blower device 140 (FIG. 1) or other source (e.g., compressed storage tank) configured to provide a flow of gas 148 to at least one gas inlet 146, and thereby provide the flow of gas 148 to the ion flow devices 154. In some examples, the blower device 140 may include one or more fans, filters, and/or other components configured to provide a gas to the ion flow devices 154. In some examples, the system 100 may include an exhaust device 142 (FIG. 1) configured to promote removal of a flow of exhaust gas 152 from the exhaust passages 162 via at least one gas outlet 150. In some examples, the exhaust device 142 may include one or more pumps. In some examples, the blower device 140 and/or the exhaust device 142 may be separate from and in fluidic communication with the wafer cleaning apparatus 132. In other examples, the blower device 140 and/or the exhaust device 142 may be components of the wafer cleaning apparatus 132.

The ion flow devices 154 may include various components configured to receive a gas, such as filtered air, from the blower device 140, electrically charge gas molecules within the gas to produce an ionized gas, and then direct the ionized gas toward the wafer 124 such that the ionized gas contacts surfaces of the wafer 124. In some examples, the ion flow devices 154 may include an ionizer 156 configured to receive the gas and generate an electric field sufficient to electrically charge gas molecules of the gas within or adjacent to the electric field to produce the ionized gas. For example, the ionizer 156 may produce ions by applying a relatively high voltage to one or more emitters (not shown), that is, components having a single, sharp point. The intense electric field generated at the tips of the emitters create and expel ions from the emitters. After the ionized gas is produced by the ionizer 156, the ionized gas may be directed to, received by, and propelled from one or more nozzles 158. The nozzles 158 may be configured to direct the ionized gas toward one or more surfaces of the wafer 124.

FIG. 2 illustrates a flow of ionized gas 170 propelled from the nozzles 158 of the ion flow devices 154. As used herein, the term ionized gas refers to a gas having a plurality of ions (172) including cations (positive charged ions), anions (negatively charged ions), or a combination thereof. In some examples, one or more surfaces of the wafer 124 may be electrically charged, that is, static electricity 164 may be present, which may cause electrostatic attraction of particles 166. When the ionized gas contacts the charged surfaces of the wafer 124, the ions 172 may be attracted to the static electricity and combine with charges of the opposite polarity. As a result, the static electricity on the wafer 124 may be neutralized and the electrostatic attraction of the particles 166 may cease.

Once the electrostatic attraction has been eliminated, the particles 166 may be carried in the ionized gas, now referred to as an exhaust gas 174, from the surfaces of the wafer 124 into the exhaust openings 160, through the exhaust passages 162, and removed by the exhaust device 142. In some examples, the exhaust openings 160, exhaust passages 162, and the exhaust device 142 may be configured to remove all or substantially all of the exhaust gas through the exhaust passages 162 such that the particles therein do not contaminate other areas of the wafer 124 or the transfer chamber 130. For example, the exhaust openings 160 may be positioned on both sides of each of the ion flow devices 154, that is, upstream and downstream of the nozzles 158 relative to a direction of movement 168 of the wafer 124 through the passage 134. The exhaust openings 160 are in fluidic communication with the surfaces of the wafer 124 and the flow of the exhaust gas 174 produced by the exhaust device 142 is sufficient to pull all or substantially all of the exhaust gas 174 into the exhaust openings 160. In some examples, a velocity of the flow of the exhaust gas 174 may exceed a velocity of the flow of ionized gas 170 propelled from the nozzles 158. In some examples, the velocity of the ionized gas exiting the nozzles 158 may be between about 1050 and 1600 L/min, and the velocity of the exhaust gas entering the exhaust openings 160 may be between about 1350 and 2050 L/min. In some examples, a ratio of the velocity of the exhaust gas divided by the velocity of the ionized gas may be between about 1.15 and 1.40, such as between about 1.20 and 1.35, such as between about 1.25 and 1.30, such as about 1.28.

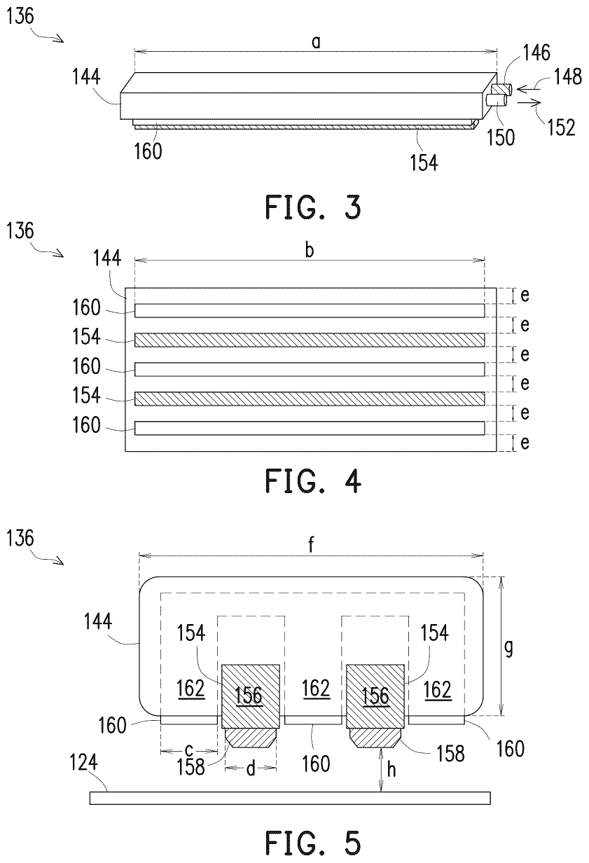

FIGS. 3-5 illustrate various views of the exemplary upper particle-removing device 136. In this example, the body 144 has a rectangular profile, and the ion flow devices 154 and the exhaust openings 160 adjacent thereto have elongated areas of coverage on a face of the body 144. The ion flow devices 154 and the exhaust openings 160 are disposed in an alternating pattern such that at least one of the exhaust openings 160 is positioned on each side of the ion flow devices 154. Notably, the upper particle-removing device 136 and the lower particle-removing device 138 are not limited to any particular quantity of the ion flow devices 154 and the exhaust openings 160, or limited to any particular arrangement pattern thereof. Further, the ion flow devices 154 and the exhaust openings 160 are schematically represented by rectangular regions. However, it should be understood that the ion flow devices 154 may include a plurality of the nozzles 158 positioned along the represented rectangular regions represented in the ion flow devices 154. Similarly, the exhaust openings 160 may include a plurality of exhaust openings 160 positioned along the rectangular regions represented in the exhaust openings 160. In some examples, the ion flow devices 154 are configured to produce an elongated wall of flow of the ionized gas perpendicular to a direction of movement of the object (e.g., the direction of movement 168 of the wafer 124 in FIG. 2). In some examples, the elongated wall of flow of the ionized gas has an elongated dimension that exceeds a dimension of the object (e.g., the wafer 124) that is parallel to the elongated dimension such that an entirety of the surface of the object is cleaned by the ionized gas.

The upper particle-removing device 136 and the lower particle-removing device 138 may have various dimensions, for example, depending on the available space within the transfer chamber 130, the level of particle-removal desired, and/or the object being cleaned (e.g., the wafer 124). In some examples, the body 144 may have a longitudinal dimension (a) of about 300 mm or greater. In some examples, the exhaust openings 160 and/or the ion flow devices 154 may have longitudinal dimensions (b) of about 300 mm or greater. In some examples, the dimension (a) of the body 144 may be greater than the dimension (b) of the ion flow devices 154 and/or the exhaust openings 160. In some examples, the exhaust openings 160 may have a dimension (c) of about 10 mm or greater. In some examples, the ion flow devices 154 may have a dimension (d) of about 0.5 to 10 mm of greater. In some examples, the ion flow devices 154 and the exhaust openings 160 may be spaced apart by a dimension (e), wherein c/e≥1. In some examples, the body may have a dimension (f) and a dimension (g), wherein f/g≥2. A dimension(s) between the nozzles 158 and the surface of the wafer 124 may be equal to or greater than one half of a height of the second interface door 120 and/or a door to the load lock module 118.

In some examples, the wafer cleaning apparatus 132 may include a monitoring device 176 that is functionally coupled to and/or in fluidic communication with one or more of the exhaust passages 162. The monitoring device 176 may be configured to monitor various conditions within one or more of the exhaust passages 162, such as pressure, concentration of the particles 166, etc. In some examples, the monitoring device 176 may include one or more sensors.

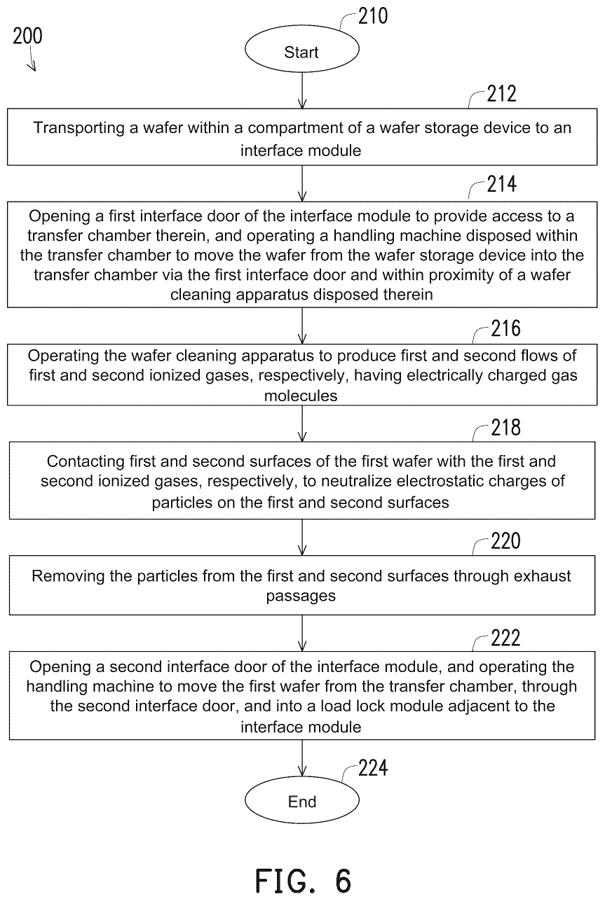

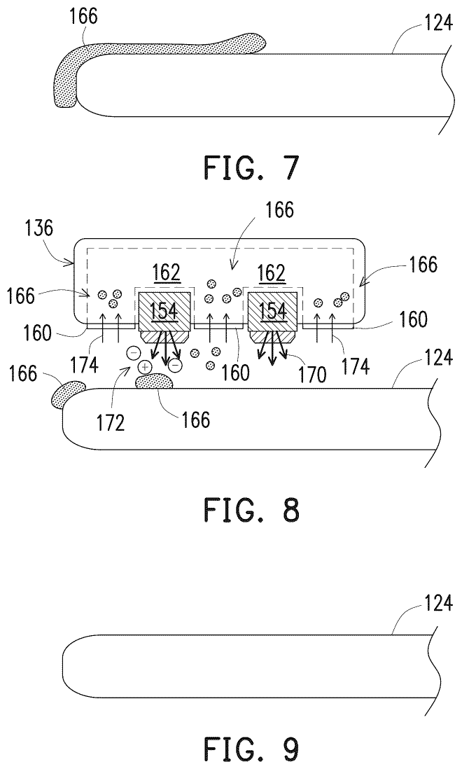

Referring to FIG. 6, an exemplary method 200 is presented for cleaning an object. For convenience, the method 200 is described herein in reference to removing particles from a semiconductor wafer, such as the wafer 124, during a semiconductor manufacturing process; however, the method 200 is not limited to any particular application and may be used to clean other types of objects. Various aspects of the method 200 will be described in reference to FIGS. 7-9.

The method 200 may start at 210.

At 212, the method 200 includes transporting a wafer within a compartment of a wafer storage device (e.g., the wafer storage device 114) to an interface module (e.g., the interface module 110).

At 214, the method 200 includes opening a first interface door of the interface module to provide access to a transfer chamber therein, and operating a handling machine disposed within the transfer chamber to move the wafer from the wafer storage device into the transfer chamber via the first interface door and within proximity of a wafer cleaning apparatus disposed therein. In some examples, one or more surfaces of the wafer may have particles or contaminants disposed thereon. For example, FIG. 7 represents the wafer 124 having an accumulation of particles 166 disposed thereon.

At 216, the method 200 includes operating the wafer cleaning apparatus to produce first and second flows of first and second ionized gases, respectively, having electrically charged gas molecules. For example, FIG. 8 represents a particle-removing device 136 as propelling a flow of ionized gas 170 from ion flow devices 154 toward the wafer 124.

At 218, the method 200 includes contacting first and second surfaces of the first wafer with the first and second ionized gases, respectively, to neutralize electrostatic charges of particles on the first and second surfaces. For example, FIG. 8 represents the ionized gas 170 as including ions 172 that are neutralizing the surfaces of the wafer 124 and thereby reducing or eliminating the attraction of the particles 166 to the surface of the wafer 124.

At 220, the method 200 includes removing the particles from the first and second surfaces through exhaust passages. For example, FIG. 8 represents the particles 166 as being removed through the exhaust passages 162 in an exhaust gas 174. In some examples, the method 200 may include spraying the surfaces of the wafer 124 with a filtered gas subsequent to cleaning with the particle-removing device 136. FIG. 9 represents the wafer 124 after cleaning with the particle-removing device 136.

At 222, the method 200 includes opening a second interface door of the interface module, and operating the handling machine to move the first wafer from the transfer chamber, through the second interface door, and into a load lock module adjacent to the interface module.

The method 200 may end at 224.

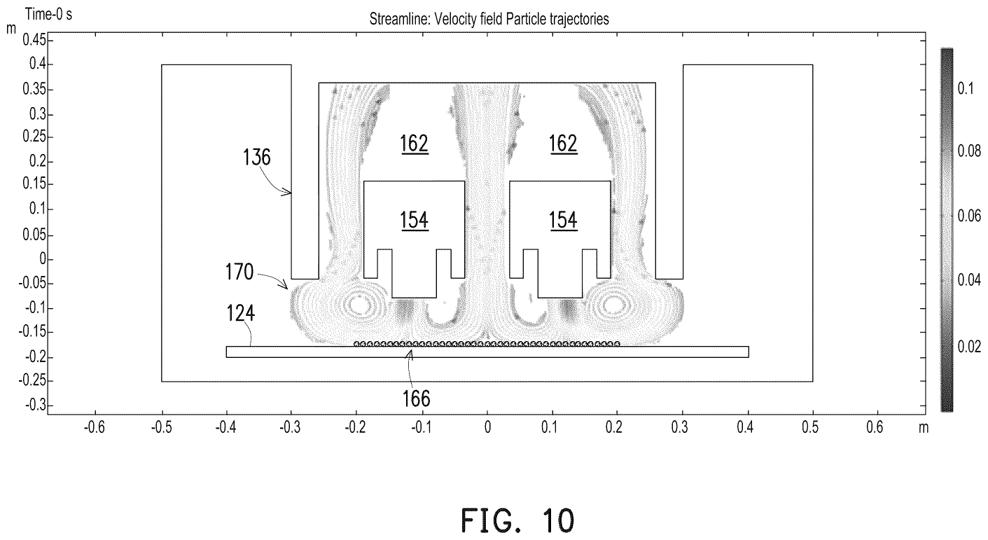

FIGS. 10-12 present results of various experimental investigations leading to aspects of some of the embodiments disclosed herein. Specifically, FIGS. 10-12 indicate results of software modeling of a surface of the wafer 124 being cleaned by a particle-removing device 136, substantially similar in function as previously described for the upper particle-removing device 136 or the lower particle-removing device 138. In this experimental investigation, the particle-removing device 136 includes two ion flow devices 154 and three exhaust openings 160 in fluidic communication with exhaust passages 162. FIGS. 10-12 represent positions of particles at times 0 sec, 3.2 sec, and 7.9 sec, respectively, as a flow of ionized gas 170 (represented by lines shaded to illustrate flow rate) is propelled from the ion flow devices 154, contacts the wafer 124, and is removed through the exhaust passages 162. As represented, the ionized gas 170 is entirely or substantially removed through the exhaust passages 162 and does not leak out sides of the particle-removing device 136.

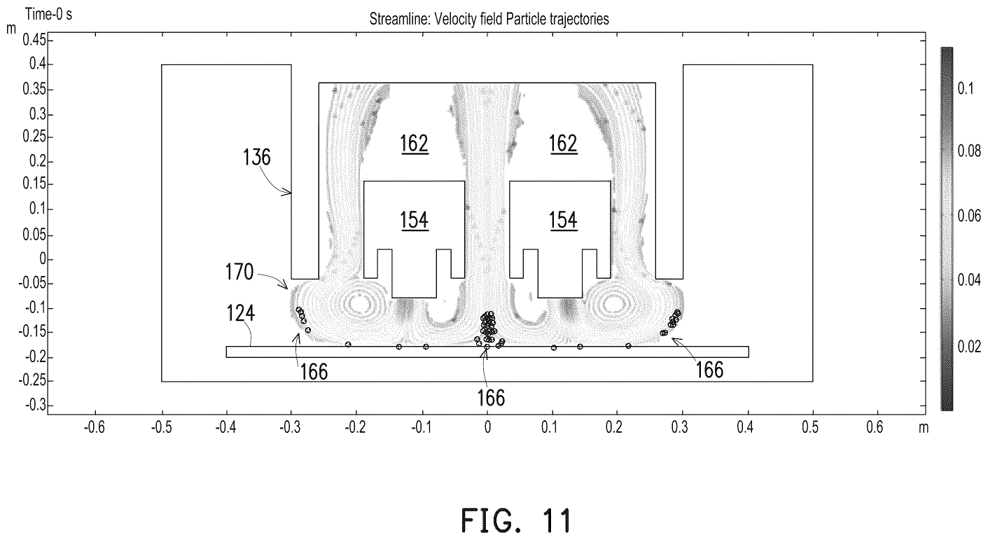

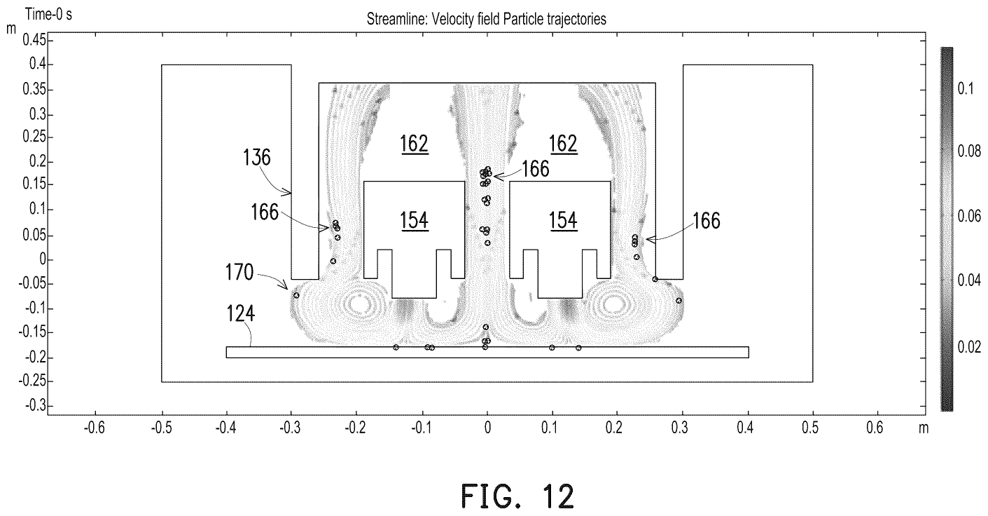

Initially in FIG. 10, the particles 166 are positioned on surfaces of the wafer 124. At a time of 3.2 seconds in FIG. 11, many of the particles 166 have moved and accumulated based on interactions with the ionized gas 170. Some of the particles 166 have begun to lift from the wafer 124 into the ionized gas 170. At a time of 7.9 seconds in FIG. 12, a significant amount of the particles 166 had separated from the wafer 124 and traveled into the exhaust passages 162 with the ionized gas 170.

The present disclosure therefore provides systems and methods for cleaning objects, such as semiconductor wafers during a semiconductor fabrication process. The systems and methods are capable of removing particles attracted to surfaces of the object due to electrostatic attraction. In some examples, the system and methods may be capable of efficiently removing particles from wafer surfaces, for example, reducing defects by up to 97 percent for five micrometer particles. Various particle types on wafer surfaces may be removed by the systems and methods such as, for example, particles disposed on the surfaces of the wafers due to falling weight, molecular attraction, static electricity, and/or moisture.

In accordance with an embodiment, an apparatus is provided that includes at least a first ion flow device that includes: a first ionizer configured to receive a filtered gas and generate a first electric field sufficient to electrically charge gas molecules of the filtered gas within or adjacent to the first electric field to produce a first ionized gas, and a first nozzle configured to receive the first ionized gas from the first ionizer and expel the first ionized gas toward a first surface of an object, wherein the first ionized gas is configured to neutralize electrostatic charges of particles on the first surface of the object upon contact between the first ionized gas and the first surface; at least a first blower device configured to propel the filtered gas to the first ionizer, through or adjacent to the first electric field produced thereby, and out of the first nozzle; a first passage disposed on a first side of the first ion flow device, wherein the first passage is in fluidic communication with the first surface of the object; a second passage disposed on a second side of the first ion flow device opposite the first side, wherein the second passage is in fluidic communication with the first surface of the object; and at least a first exhaust device configured to flow the first ionized gas from the first surface of the object through the first passage and the second passage and thereby remove the particles from the first surface of the object through the first passage and the second passage.

In accordance with another embodiment, a wafer transfer system is provided. The wafer transfer system includes a wafer storage device configured to transport a wafer within a compartment thereof, an interface module that includes a transfer chamber defined by walls of the interface module, the interface module including a first interface door for receiving the wafer into the transfer chamber and a second interface door for transporting the wafer from the transfer chamber, a load lock module adjacent to the interface module and configured to receive the wafer from the transfer chamber of the interface module, a handling machine disposed within the transfer chamber of the interface module and configured to move the wafer from the wafer storage device and into the transfer chamber via the first interface door, through the transfer chamber, and into the load lock module via the second interface door, and a wafer cleaning apparatus disposed within the transfer chamber of the interface module. The wafer cleaning apparatus is configured to produce an ionized gas from a source of a filtered gas, direct the ionized gas toward a first surface of the wafer, wherein the ionized gas is configured to neutralize electrostatic charges of particles on the first surface of the wafer upon contact between the ionized gas and the first surface, and remove the ionized gas from the first surface of the wafer and thereby remove the particles from the first surface of the wafer.

In accordance with yet another embodiment, a method is provided. The method includes transporting a wafer within a compartment of a wafer storage device to an interface module, opening a first interface door of the interface module to provide access to a transfer chamber defined by walls of the interface module, operating a handling machine disposed within the transfer chamber of the interface module to move the wafer from the wafer storage device and into the transfer chamber via the first interface door, operating the handling machine to move the wafer through the transfer chamber to within proximity of a wafer cleaning apparatus disposed within the transfer chamber of the interface module, operating the wafer cleaning apparatus to clean the wafer, opening a second interface door of the interface module, and operating the handling machine to move the wafer from the transfer chamber of the interface module, through the second interface door, and into a load lock module adjacent to the interface module. Operating the wafer cleaning apparatus includes producing a first flow of a first ionized gas having electrically charged gas molecules and a second flow of a second ionized gas having electrically charged gas molecules, contacting a first surface of the wafer with the first ionized gas to neutralize electrostatic charges of particles on the first surface on a first side of the wafer upon contact between the first ionized gas and the first surface, and contact a second surface on a second side of the wafer opposite the first side with the second ionized gas to neutralize electrostatic charges of the particles on the second surface of the wafer upon contact between the second ionized gas and the second surface, and removing the particles from the first surface and the second surface of the wafer through exhaust passages.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An apparatus, comprising:
at least a first ion flow device that includes:
a first ionizer configured to receive a filtered gas and generate a first electric field sufficient to electrically charge gas molecules of the filtered gas within or adjacent to the first electric field to produce a first ionized gas; and
a first nozzle configured to receive the first ionized gas from the first ionizer and expel the first ionized gas toward a first surface of an object, wherein the first ionized gas is configured to neutralize electrostatic charges of particles on the first surface of the object upon contact between the first ionized gas and the first surface;
at least a first blower device configured to propel the filtered gas to the first ionizer, through or adjacent to the first electric field produced thereby, and out of the first nozzle;
a first passage disposed on a first side of the first ion flow device, wherein the first passage is in fluidic communication with the first surface of the object;
a second passage disposed on a second side of the first ion flow device opposite the first side, wherein the second passage is in fluidic communication with the first surface of the object; and
at least a first exhaust device configured to flow the first ionized gas from the first surface of the object through the first passage and the second passage and thereby remove the particles from the first surface of the object through the first passage and the second passage.

2. The apparatus of claim 1, further comprising one or more additional ion flow devices that each include an additional ionizer configured to receive the filtered gas and generate an additional electric field sufficient to electrically charge gas molecules of the filtered gas within or adjacent to the additional electric field to produce additional ionized gas, and an additional nozzle configured to receive the additional ionized gas and expel the additional ionized gas toward the first surface of the object, wherein the additional ionized gas is configured to neutralize the electrostatic charges of the particles on the first surface of the object upon contact between the additional ionized gas and the first surface.

3. The apparatus of claim 2, further comprising additional passages disposed on sides of each of the one or more additional ion flow devices, wherein the additional passages are in fluidic communication with the first surface of the object, wherein the first exhaust device is configured to flow the additional ionized gas from the first surface of the object through the additional passages and thereby remove the particles from the first surface of the object through the additional passages.

4. The apparatus of claim 1, wherein the first ion flow device is configured to produce an elongated wall of flow of the first ionized gas perpendicular to a direction of movement of the object.

5. The apparatus of claim 1, wherein the first surface is a first side of the object, and the apparatus further includes:
an additional ion flow device that includes:
an additional ionizer configured to receive the filtered gas and generate an additional electric field sufficient to electrically charge gas molecules of the filtered gas within or adjacent to the additional electric field to produce an additional ionized gas; and
an additional nozzle configured to receive the additional ionized gas and expel the additional ionized gas toward a second surface on a second side of the object opposite the first side thereof, wherein the additional ionized gas is configured to neutralize electrostatic charges of additional particles on the second surface of the object upon contact between the additional ionized gas and the second surface;
a third passage disposed on a first side of the additional ion flow device, wherein the third passage is in fluidic communication with the second surface of the object;
a fourth passage disposed on a second side of the additional ion flow device opposite the first side, wherein the fourth passage is in fluidic communication with the second surface of the object; and
wherein the first blower device or an additional blower device is configured to propel the filtered gas to the additional ion flow device, through or adjacent to the additional electric field produced thereby, and out of the additional nozzle,
wherein at least the first exhaust device or at least one additional exhaust device is configured to flow the additional ionized gas from the second surface of the object through the third passage and the fourth passage and thereby remove the additional particles from the second surface of the object through the third passage and the fourth passage.

6. The apparatus of claim 1, further comprising a monitoring device configured to monitor pressure in the first passage and the second passage.

7. The apparatus of claim 1, wherein the object is a wafer at an intermediate stage of a semiconductor manufacturing process.

8. A wafer transfer system, comprising:
a wafer storage device configured to transport a wafer within a compartment thereof;
an interface module that includes a transfer chamber defined by walls of the interface module, the interface module including a first interface door for receiving the wafer into the transfer chamber and a second interface door for transporting the wafer from the transfer chamber;
a load lock module adjacent to the interface module and configured to receive the wafer from the transfer chamber of the interface module;
a handling machine disposed within the transfer chamber of the interface module and configured to move the wafer from the wafer storage device and into the transfer chamber via the first interface door, through the transfer chamber, and into the load lock module via the second interface door; and
a wafer cleaning apparatus disposed within the transfer chamber of the interface module, wherein the wafer cleaning apparatus is configured to:
produce an ionized gas from a source of a filtered gas;
direct the ionized gas toward a first surface of the wafer, wherein the ionized gas is configured to neutralize electrostatic charges of particles on the first surface of the wafer upon contact between the ionized gas and the first surface; and
remove the ionized gas from the first surface of the wafer and thereby remove the particles from the first surface of the wafer.

9. The wafer transfer system of claim 8, wherein the wafer cleaning apparatus includes:
at least two ion flow devices that each include an ionizer configured to receive the filtered gas and generate an electric field sufficient to electrically charge gas molecules of the filtered gas within or adjacent to the electric field to produce the ionized gas, and a nozzle configured to receive the ionized gas and expel the ionized gas toward the first surface of the wafer;
passages disposed on sides of each of the at least two ion flow devices, wherein the passages are in fluidic communication with the first surface of the wafer; and
at least one exhaust device configured to flow the ionized gas from the first surface of the wafer through the passages and thereby remove the particles from the first surface of the wafer through the passages.

10. The wafer transfer system of claim 8, wherein the wafer cleaning apparatus is configured to produce an elongated wall of flow of the ionized gas perpendicular to a direction of movement of the wafer.

11. The wafer transfer system of claim 8, wherein the first surface is a first side of the wafer, and the wafer cleaning apparatus is configured to:
direct the ionized gas toward a second surface on a second side of the wafer, wherein the ionized gas is configured to neutralize electrostatic charges of the particles on the second surface of the wafer upon contact between the ionized gas and the second surface; and
remove the ionized gas from the second surface of the wafer and thereby remove the particles from the second surface of the wafer.

12. The wafer transfer system of claim 8, further comprising a monitoring device configured to monitor pressure in one or more passages through which the ionized gas is transported while removing the ionized gas from the first surface of the wafer.

13. The wafer transfer system of claim 8, wherein the handling machine includes a robotic arm whose movement speed is controllable with a vacuum system.

14. A method, comprising:
transporting a wafer within a compartment of a wafer storage device to an interface module;
opening a first interface door of the interface module to provide access to a transfer chamber defined by walls of the interface module;
operating a handling machine disposed within the transfer chamber of the interface module to move the wafer from the wafer storage device and into the transfer chamber via the first interface door;
operating the handling machine to move the wafer through the transfer chamber to within proximity of a wafer cleaning apparatus disposed within the transfer chamber of the interface module;
operating the wafer cleaning apparatus to clean the wafer by:
produce a first flow of a first ionized gas having electrically charged gas molecules and a second flow of a second ionized gas having electrically charged gas molecules;
contact a first surface of the wafer with the first ionized gas to neutralize electrostatic charges of particles on the first surface on a first side of the wafer upon contact between the first ionized gas and the first surface, and contact a second surface on a second side of the wafer opposite the first side with the second ionized gas to neutralize electrostatic charges of the particles on the second surface of the wafer upon contact between the second ionized gas and the second surface; and
remove the particles from the first surface and the second surface of the wafer through exhaust passages;
opening a second interface door of the interface module; and
operating the handling machine to move the wafer from the transfer chamber of the interface module, through the second interface door, and into a load lock module adjacent to the interface module.

15. The method of claim 14, wherein operating the wafer cleaning apparatus includes:
operating at least two ion flow devices that each include an ionizer configured to receive filtered gas and generate an electric field sufficient to electrically charge gas molecules of the filtered gas within or adjacent to the electric field to produce the first ionized gas and the second ionized gas, and nozzles configured to receive one of the first ionized gas of the second ionized gas and expel the first ionized gas of the second ionized gas toward the first surface or the second surface of the wafer;
removing the first ionized gas and the second ionized gas through passages disposed on sides of each of the at least two ion flow devices, wherein each of the passages are in fluidic communication with one of the first surface of the second surface of the wafer; and
operating an exhaust device to flow the first ionized gas and the second ionized gas from the first surface and the second surface of the wafer through the passages and thereby remove the particles from the first surface and the second surface of the wafer through the passages.

16. The method of claim 14, wherein operating the wafer cleaning apparatus includes producing a first elongated wall of flow of the first ionized gas and a second elongated wall of flow of the second ionized gas both perpendicular to a direction of movement of the wafer.

17. The method of claim 14, further comprising monitoring, with a monitoring device, pressure in one or more passages through which the first ionized gas or the second ionized gas are transported while removing the first ionized gas and the second ionized gas from the first surface and the second surface of the wafer.

18. The method of claim 14, wherein operating the wafer cleaning apparatus is performed at an intermediate stage of a semiconductor manufacturing process.

19. The method of claim 14, wherein operating the handling machine includes controlling a movement speed of a robotic arm with a vacuum system.

20. The method of claim 14, further comprising spraying the first surface and the second surface with filtered air after operating the wafer cleaning apparatus to clean the wafer and prior to opening the second interface door of the interface module.
